(19) United States
(12) Patent Application Publication
(10) Pub. No.: US 2024/0280222 A1
(43) Pub. Date: Aug. 22, 2024

(54) TRANSPORT CONTAINERS WITH PERMANENT MAGNETS AND ASSOCIATED METHODS

(71) Applicant: Polarean, Inc., Durham, NC (US)

(72) Inventor: Matthew Linford, Chapel Hill, NC (US)

(21) Appl. No.: 18/436,641

(22) Filed: Feb. 8, 2024

Related U.S. Application Data
(60) Provisional application No. 63/486,111, filed on Feb. 21, 2023.

(51) Int. Cl. F17C 13/00; F17C 1/00; G01R 33/28

(52) U.S. Cl. CPC F17C 13/00; F17C 1/00; G01R 33/282; F17C 2203/0602; F17C 2221/07

(57) ABSTRACT

A transport container includes first and second sets or arrays permanent magnets arranged to provide a magnetic holding field for protecting hyperpolarized gas during storage and/or transport. The permanent magnets can be flat permanent magnets positioned on cooperating first and second spaced apart metal pans and be configured to project the magnetic holding field in space about an internal holding chamber for gas containers.

### RELATED APPLICATIONS

This patent application claims the benefit of and priority to U.S. Provisional Application Ser. No. 63/486,111 filed Feb. 21, 2023, the contents of which are hereby incorporated by reference as if recited in full herein.

### FIELD OF THE INVENTION

The present invention relates to the transport of a target gas and is particularly suitable for transporting hyperpolarized ¹²⁹Xe gas for use in medical magnetic resonance imaging (“MRI”) applications.

### BACKGROUND

Conventionally, MRI has been used to produce images by exciting the nuclei of hydrogen atoms (present in water molecules) in the human body. MRI imaging with polarized noble gases can produce improved images of certain areas and regions of the body. Polarized Helium-3 (“³He”) and Xenon-129 (“¹²⁹Xe”) have been found to be particularly suited for this purpose.

Hyperpolarizers are used to produce and accumulate polarized noble gases. Hyperpolarizers artificially enhance the polarization of certain noble gas nuclei (such as ¹²⁹Xe or ³He) over the natural or equilibrium levels, i.e., the Boltzmann polarization. Such an increase is desirable because it enhances and increases the Magnetic Resonance Imaging (“MRI”) signal intensity, allowing physicians to obtain better images of the substance in the body. See U.S. Pat. No. 5,642,625 to Cates et al. and U.S. Pat. No. 5,545,396 to Albert et al., the contents of which are hereby incorporated herein by reference as if recited in full herein.

Unfortunately, the polarized state of the gas is sensitive to handling and environmental conditions and can, undesirably, decay from the polarized state relatively quickly.

A “T₁” decay time constant associated with the hyperpolarized gas' longitudinal relaxation is often used to characterize the length of time it takes a gas sample to depolarize in a given situation. The handling of the hyperpolarized gas is critical because of the sensitivity of the hyperpolarized state to environmental and handling factors and thus the potential for undesirable decay of the gas from its hyperpolarized state prior to the planned end use, e.g., delivery to a patient for imaging. Processing, transporting, and storing the hyperpolarized gases—as well as delivering the gas to the patient or end user—can expose the hyperpolarized gases to various relaxation mechanisms such as magnetic field gradients, surface-induced relaxation, hyperpolarized gas atom interactions with other nuclei, paramagnetic impurities, and the like.

These problems can be particularly troublesome when transporting the hyperpolarized gas from a production site to a use site. In transit, the hyperpolarized gas can be exposed to many potentially depolarizing influences. There is, therefore, a need to provide improved ways to transport hyperpolarized gases so that the hyperpolarized gas is not unduly exposed to depolarizing effects during transport. Improved storage and transport methods and systems are desired so that the hyperpolarized product can retain sufficient polarization to allow effective imaging at delivery when stored and/or transported in various (potentially depolarizing) environmental conditions, and for longer time periods from the initial point of polarization than has been viable previously.

One design proposed to provide a homogeneous field in a unit for transporting and storing hyperpolarized gas products is discussed in U.S. patent application Ser. No. 09/333,571 entitled “Hyperpolarized Gas Containers, Solenoids, Transport and Storage Devices and Associated Transport and Storage Methods”, the contents of which are hereby incorporated by reference herein. However, a magnetic field generator within the transport unit used for generating the hyperpolarized gas magnetic holding field requires power to operate it. During transport or in storage, a convenient source of power may be difficult to find. Additionally, batteries with lengthy lifetimes suitable for hyperpolarized gas transport and storage can be heavy and are often large.

Another alternative is proposed in WO 99/17304. This reference proposes configuring a magnetically shielded container using opposing pole shoes to provide a unit for holding and transporting a chamber of polarized gas. Unfortunately, the shielded container is designed so as to require removal of one of the pole shoes to remove the gas chamber, thereby potentially sacrificing the homogeneity of the field. Additionally, the pole shoes can be dented or permanently magnetized during transport and storage. Physical deformation of the pole shoes which occurs during transport or normal use can unfortunately permanently destroy the homogeneity of the magnetic field. Furthermore, the pole shoes (which as described comprise mu metal or soft iron) can display hysteresis characteristics. This hysteresis can cause the pole shoes to be permanently magnetized if placed next to a magnetic field source, thereby acting as its own magnet and potentially deleteriously affecting the homogencity of the resulting permanent magnet field.

An additional alternative is proposed in U.S. patent application Ser. Nos. 08/989,604 and 09/210,020, the contents of which are hereby incorporated by reference herein. In these two patent applications, a magnetic field generator is described for the transport of hyperpolarized frozen xenon. The magnetic field generator comprises a relatively small magnet yoke and two permanent magnets mounted opposite one another on the magnet yoke. This configuration produces a magnetic field with high field strength but relatively low homogeneity. While high magnetic field strength alone can generally maintain a highly hyperpolarized state in a solid (frozen) hyperpolarized gas product, thawing prior to use produces a gaseous xenon product, which then typically requires that the field be homogeneous to reduce the likelihood of rapid depolarization due to gradient-induced relaxation.

Another alternative is described in U.S. Pat. No. 7,066,319, which describes the use of strategically placed permanent magnets, the contents of which are hereby incorporated by reference as if recited in full herein.

Despite the above, there remains a need for alternative transport containers that provide an easy to access internal space for gas containers while inhibiting T₁ relaxation of hyperpolarized gas in the gas containers held therein.

### SUMMARY

Embodiments of the present invention provide a transport container which can hold hyperpolarized gas in one or more gas containers for extended periods of time, such that the hyperpolarized gas is sufficiently viable to produce clinically useful images at a spatially and/or temporally separated point in time from the point of polarization.

Embodiments of the present invention provide transport containers that have first and second spaced apart metal pans, each having arrays of (flat) permanent magnets arranged on primary surfaces of top and sidewalls thereof that cooperate to provide a magnetic field in an enclosed internal space.

Embodiments of the present invention are directed to a transport container for transporting one or more gas containers of hyperpolarized gas products. The transport container includes a first pan having a first recessed chamber and a second pan having a second recessed chamber. The second pan is spaced apart from the first pan, aligned with and facing the first pan with the first recessed chamber facing the second recessed chamber. The transport container also includes a first set of magnets on the first pan and a second set of magnets on the second pan.

The first and second pans can be ferromagnetic metal.

The transport container can further include at least one spacer positioned between the first pan and the second pan that can define at least part of an internal chamber.

The transport container can further include a first spacer and a second spacer arranged between the first and second pans. The first spacer can have sidewalls that are shorter than sidewalls of the second spacer. The first and second spacers can have an open center through channel that are aligned and cooperate with the first and second pans to provide at least part of an internal chamber configured to hold at least one gas container.

The first and second spacers can be rectangular and have a foam body.

The second spacer can have a lip that can reside inside the second recessed chamber.

The transport container can further include an outer case with cooperating first and second case members. The outer case can hold the first and second pans therein.

The outer case can have a polymer or co-polymer molded body.

The first and second pans can each have a respective primary wall and four sidewalls. The four sidewalls can define a perimeter of a respective pan, can be orthogonal to the primary wall and can surround the respective recessed chamber under or above the primary wall. The first and second sets of magnets can be provided as rare earth permanent magnets.

The rare earth permanent magnets can include neodymium.

The first and second sets of magnets can be arranged in rows and columns or rows or columns across and/or along the primary wall of respective first and second pans and also with at least one row arranged to extend across each of the four sidewalls.

The first and second sets of magnets can be magnets that include neodymium and can be arranged in the columns and rows on the primary wall of respective first and second pans.

The transport container can also have a single row of permanent magnets that have neodymium arranged about each of four sidewalls of each of the first and second pans. The single row can be spaced inwardly apart a distance from the primary wall to define a gap space therebetween.

The first and second sets of magnets can be provided as closely spaced planar magnets and wherein the planar magnets can be rare earth magnets.

The first and second pans can be galvanic steel.

The first and second sets of magnets can define a magnetic field in a range of about 20 Gauss to about 80 Gauss over a volume of (at least) about 530 in³ of the internal chamber.

The transport container can have a weight in a range of about 10 pounds to about 25 pounds.

The magnets of the first and second sets of magnets can have a common size and shape with a thickness in a range of about 1/16 inch to about ¼ of an inch, and the magnets can have a rated holding power of about 42.5 lb or greater and a surface gauss rating of at least about 1700.

The transport container can further include at least one bag of hyperpolarized ¹²⁹Xe gas in the internal chamber.

The at least one bag of hyperpolarized ¹²⁹Xe gas in the internal chamber can be provided as three, each oriented on-end with an outlet tube facing a right or left side of the transport container, when the first and second pans are oriented horizontally.

The first and second pans can be polygonal and have a length and a width in a range of 9 inches to 2 feet.

The primary walls can have a length and width in a range of about 9 inches to about 2 feet. The sidewalls can have a height in a range of one inch to five inches, optionally about two inches.

The transport container can further include an outer case with a lid and a bottom. The lid can hold the first pan and a first foam spacer and can pivot away from the bottom to open and close. The bottom can hold the second pan and a second foam spacer facing the first foam spacer.

The first foam spacer can have a first open channel and the second foam spacer has a second open channel. The first open channel can be aligned with the second open channel and the first and second open channels define at least a portion of the internal chamber.

The first foam spacer and/or the second foam spacer can be configured to hold the at least one gas container between the first and second pans.

It is noted that aspects of the invention described with respect to one embodiment, may be incorporated in a different embodiment although not specifically described relative thereto. That is, all embodiments and/or features of any embodiment can be combined in any way and/or combination for any number of desired activities and/or any degree of activity performance complexity or variability. Applicant reserves the right to change any originally filed claim or file any new claim accordingly, including the right to be able to amend any originally filed claim to depend from and/or incorporate any feature of any other claim although not originally claimed in that manner. These and other objects and/or aspects of the present invention are explained in detail in the specification set forth below.

The foregoing and other objects and aspects of the present invention are explained in detail herein.

### BRIEF DESCRIPTION OF THE DRAWINGS

Other features of the present invention will be more readily understood from the following detailed description of exemplary embodiments thereof when read in conjunction with the accompanying drawings.

FIG. 1 is an exploded view of components of a transport container according to embodiments of the present invention.

FIG. 2 is a top/front perspective view of a closed transport container according to embodiments of the present invention.

FIG. 3 is a top/front perspective view of the transport container shown in FIG. 2 in an open configuration according to embodiments of the present invention

FIG. 4 is a side perspective, closed configuration of first and second pans and first and second spacers providing internal components of the transport container shown in FIG. 1.

FIG. 5A is a side perspective view of the first and second pans shown without the spacers of FIG. 4.

FIG. 5B is a side perspective view of another embodiment of magnets attached to the first and second pans shown without the spacers of FIG. 4.

FIG. 6 is a schematic lateral section view of the first and second pans with example sets of magnet arrays showing magnet orientations relative to a holding chamber and a gap space between the first and second pans according to embodiments of the present invention.

FIG. 7 is a simulation of magnetic field direction generated by a planar set/array of spaced apart magnets.

FIG. 8 is a simulation of magnetic field direction generated by the planar set/array of spaced apart magnets in combination with a metal support surface defining a flat pole member according to embodiments of the present invention.

FIG. 9 is a simulation of magnetic field direction generated by the planar set/array of spaced apart magnets in combination with the metal support surface shown in FIG. 8 in combination with magnets placed orthogonal to the metal support surface on a sidewall/flange according to embodiments of the present invention.

### DETAILED DESCRIPTION

The present invention will now be described more fully hereinafter with reference to the accompanying figures, in which preferred embodiments of the invention are shown. This invention may, however, be embodied in many different forms and should not be construed as limited to the embodiments set forth herein.

Like numbers refer to like elements throughout. In the figures, layers, regions and/or components may be exaggerated for clarity. The word “Figure” is used interchangeably with the abbreviated forms “FIG.” and “Fig.” in the text and/or drawings. Broken lines illustrate optional features or operations unless specified otherwise. In the description of the present invention that follows, certain terms are employed to refer to the positional relationship of certain structures relative to other structures.

The terminology used herein is for the purpose of describing particular embodiments only and is not intended to be limiting of the invention. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items. As used herein, phrases such as “between X and Y” and “between about X and Y” should be interpreted to include X and Y. As used herein, phrases such as “between about X and Y” mean “between about X and about Y.” As used herein, phrases such as “from about X to Y” mean “from about X to about Y.”

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the specification and relevant art and should not be interpreted in an idealized or overly formal sense unless expressly so defined herein. Well-known functions or constructions may not be described in detail for brevity and/or clarity.

It will be understood that when an element is referred to as being “on”, “attached” to, “connected” to, “coupled” with, “contacting”, etc., another element, it can be directly on, attached to, connected to, coupled with or contacting the other element or intervening elements may also be present. In contrast, when an element is referred to as being, for example, “directly on”, “directly attached” to, “directly connected” to, “directly coupled” with or “directly contacting” another element, there are no intervening elements present. It will also be appreciated by those of skill in the art that references to a structure or feature that is disposed “adjacent” another feature may have portions that overlap or underlie the adjacent feature.

It will also be understood that, although the terms first, second, etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present invention. The sequence of operations (or steps) is not limited to the order presented in the claims or figures unless specifically indicated otherwise.

Spatially relative terms, such as “under”, “below”, “lower”, “over”, “upper” and the like, may be used herein for ease of description to describe one element or feature's relationship to another element(s) or feature(s) as illustrated in the figures. It will be understood that the spatially relative terms are intended to encompass different orientations of the data or information in use or operation in addition to the orientation depicted in the figures. For example, if data in a window view of the system in the figures is inverted, elements described as “under” or “beneath” other elements or features would then be oriented “over” the other elements or features. Thus, the exemplary term “under” can encompass both an orientation of over and under. The display view may be otherwise oriented (rotated 90 degrees or at other orientations) and the spatially relative descriptors used herein interpreted accordingly. Similarly, the terms “upwardly”, “downwardly”, “vertical”, “horizontal” and the like are used herein for the purpose of explanation only unless specifically indicated otherwise.

In some embodiments, the transport container is used to transport gas containers of polarized ¹²⁹Xe gas produced and formulated to be suitable for internal (inhalable) pharmaceutical human or animal medical purposes.

The term “about” means within plus or minus 10% of a recited number.

The term “polarization friendly” means that the device is configured and formed of materials and/or chemicals that do not induce or cause more than di minimis decay (e.g., less than about 2%) of the polarization of the polarized noble gas, e.g., ¹²⁹Xe.

As used herein, the terms “hyperpolarize” and “polarize” are used interchangeably and mean artificially enhanced polarization of certain noble gas nuclei over the natural or equilibrium levels. Such an increase is desirable because it allows stronger imaging signals corresponding to better MRI images of the substance and a targeted area of the body. As is known by those of skill in the art, hyperpolarization can be induced by spin-exchange with an optically pumped alkali-metal vapor or alternatively by metastability exchange. See Albert et al., U.S. Pat. No. 5,545,396, which is incorporated by reference as if recited in full herein.

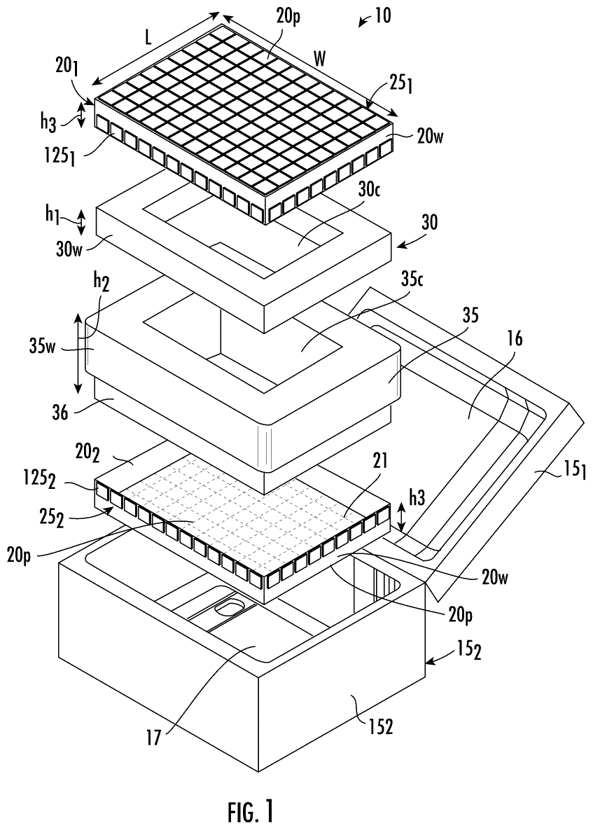

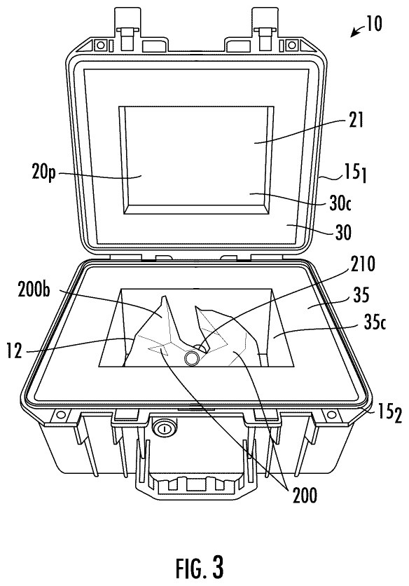

Turning now to FIGS. 1-3, an example transport container 10 is shown. As shown, the transport container 10 has an outer case 15 that encloses a first pan 20₁ and a second pan 20₂. The transport container 10 has an internal chamber 12 configured to hold at least one gas container 200 (FIG. 3). The first pan 20₁ comprises a first set and/or array of magnets 251. The second pan 20₂ comprises a second set and/or array of magnets 252.

Each of the first and second pans 20₁, 20₂ has a primary wall 20p and sidewalls 20w that are orthogonal to the primary wall 20p surrounding a recessed chamber 21 that is under or above a respective primary wall 20p. The sidewalls 20w can be arranged to have a rectangular perimeter. The recessed chambers 21 face each other but are typically spaced apart by at least one spacer 35, shown as a first spacer 30 and a cooperating second spacer 35. The at least one spacer 35 can have a foam body. The at least one spacer 35 can be configured to hold the gas container(s) 200 at a location that is inward from the sidewalls 20w and primary surfaces 20p of the pans 20₁, 20₂, to position/hold/place the dose container(s) 200 in a “sweet spot” corresponding to a uniform portion of the magnetic field provided by the transport container 10.

A first set or array of magnets 251 is attached to the primary wall 20p of the first pan 20₁. A second set or array of magnets 252 is attached to the primary wall 20p of the second pan 20₂. The first and second sets or arrays of magnets 251, 252 can be provided in the same configuration. The primary walls 20p of the first and second pans 20₁, 20₂ and the first and second sets or arrays of magnets, 251, 252 are parallel and reside in different planes on each side of the internal chamber 12 (FIG. 3).

As shown, a plurality of magnets 1251 are also attached to the sidewalls 20w of the first pan 20₁ and a plurality of magnets 1252 are attached to the sidewalls 20w of the second pan 20₂.

The gaps between discrete magnets 25m in each set of magnets 251, 252, which may otherwise cause undesired distortion of a magnetic field for the internal chamber 12, can be resolved by using the respective pan 20₁, 20₂ to form a cooperating magnetic pole member that effectively extends the poles of the magnets 25m and merges them into a single pole.

A first spacer 30 can reside adjacent the first pan 20₁. A second spacer 35 can reside adjacent the second pan 20₂. Each of the first spacer 30 and the second spacer 35 can have medially positioned through channels 30c, 35c that are aligned and form part of the internal chamber 12. Although shown as a single through channel 30c, 35c, respectively, each spacer 30, 35, may have a plurality of through channels configured to hold a single gas container 200 rather than one internal chamber 12 that can hold a plurality of gas containers 200 (FIG. 3). The first spacer 30 and the second spacer 35 can each comprises a foam body.

The first spacer 30 can have a sidewall 30w with a first height h1. The second spacer 35 can have a sidewall 35w with a second height h2. The second spacer 35 can have a sidewall 35w that can merge into a lip 36 that resides a distance inside the recessed chamber 21 of the second pan 20₂. The sidewall 35w of the second spacer 35 can have a greater height than the first spacer 30; h2>h1.

The outer case 15 can be provided as a two-piece case with first and second case members 151, 152 that can be pivotably attached. The first case member 151 can have a recessed chamber 16 and the second case member 152 can have a (deeper) recessed chamber 17. Foam or other surround material can be held in one or both case members 151, 152, and be configured to receive the at least one spacer 35 (not shown).

As shown in FIG. 3, the first spacer 30 and the first pan 20₁ can reside in the first case member 151 and can open in concert with the first case member 151 (lid) of the case 15. The second spacer 35 and the second pan 20₂ can reside in the second case member 152 (bottom) to allow a user to access the internal chamber 12. As shown, when the case 15 is in the open configuration (FIG. 3), the internal surface of the primary wall 20w of the first pan 20₁ can be seen through the open channel 30c of the first spacer 30. However, it is noted that the first spacer 30 can have a closed body with or without a recessed chamber formed therein.

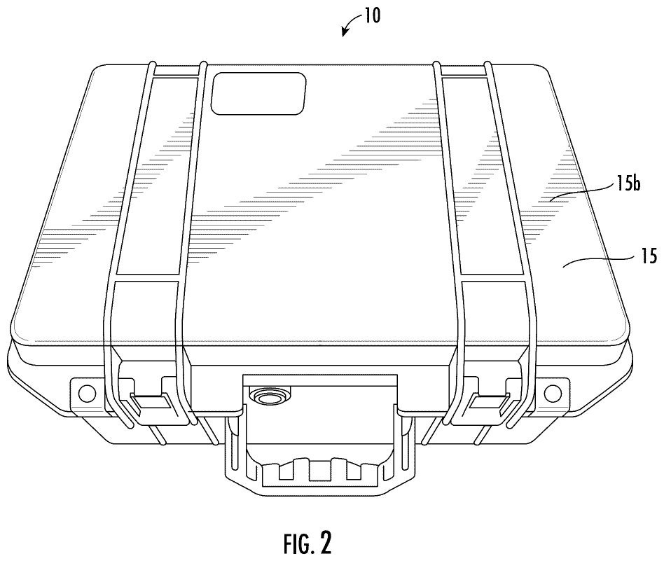

The outer case 15 can have a polymer or co-polymer molded body 15b (FIG. 2).

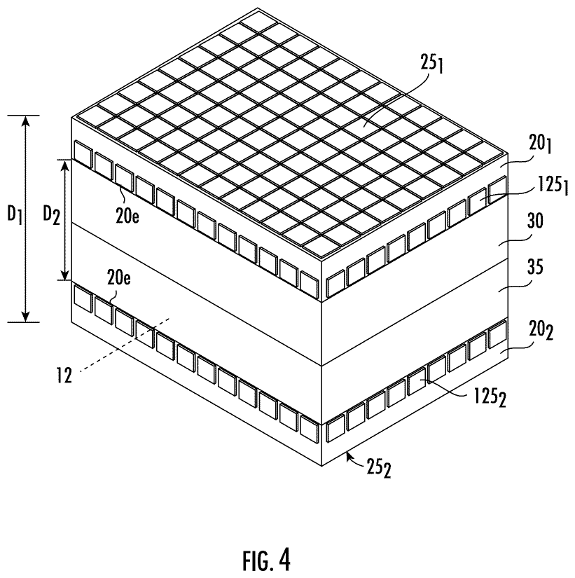

FIG. 4 shows the spacers 30, 35 and pans 20₁, 20₂ without the outer case 15 and with the pans and spacers in the closed configuration. As shown, the first and second spacers 30, 35 can abut and the first and second pans 20₁, 20₂ can be spaced apart. The primary walls 20p can be spaced apart a distance D1 in a range of about 6-10 inches, such as about 8 inches. The closest edge 20e of the sidewalls 20w can be spaced apart a distance D2 in a range of about 2-6 inches, such as about 4 inches.

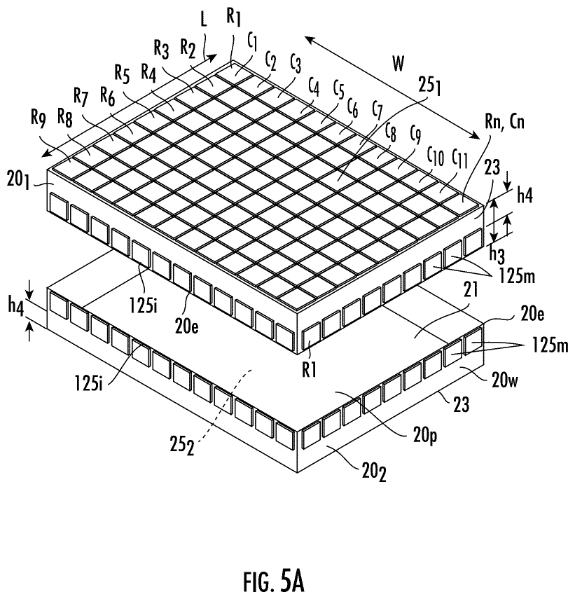

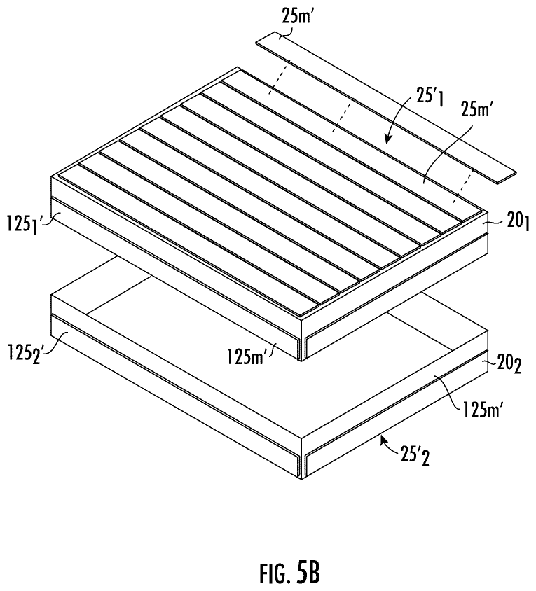

The first and second pans 20₁, 20₂ can have a height h3 (FIG. 1) that is less than the height h1 and h2 (FIG. 1). The first and second pans 20₁, 20₂ can have a width dimension “W” (FIG. 5A) and a length dimension “L” (FIG. 5A) that are both greater than the height h3 (FIG. 1). The width dimension W can be greater than the length dimension L. The length L can be in a range of 6-12 inches and the width W can be in a range of 1-2 feet, in some particular embodiments. The height h3 can be in a range of 1-5 inches, typically about 2 inches.

The first and second pans 20₁, 20₂ can be metal, typically ferromagnetic with sufficient magnetic permeability so as to define a pole member that is configured to magnetically cooperate with the discrete magnets 25m, 125m and extend poles of the magnets 25m, 125m and/or can improve a unidirectionality and strength of the magnetic field(s). The first and second pans 20₁, 20₂ can be galvanized metal in some embodiments.

The magnets 25m of the sets or arrays of magnets 251, 252 can be rare earth permanent magnets. In some embodiments, the magnets 25m comprise neodymium.

The magnets 25m of the sets or arrays of magnets 251, 252 can be arranged in rows R and/or columns C.

The transport container 10 can comprise a large number of discrete magnets 25m, 125m, typically in a range of about 20-500, such as about 300.

Referring to FIG. 5A, the discrete magnets 25m are arranged in columns C1-C12, and rows R1-R9 on the primary wall 20p. There is a single row R1 of magnets 125m on the sidewalls 20w. Other numbers and/or configurations of discrete magnets 25m, 125m may be used.

Still referring to FIG. 5A, the sets or arrays of magnets 1251, 1252, on the respective sidewalls 20w (e.g., flange) can be spaced apart from the primary wall 20p a distance h4 to define a gap space 23. The distance/height h4 is less than an overall height h3 of the sidewalls 20w. The height h4 of the gap space 23 can be 30-70% of h3.

The magnets 125m can have an inner facing side 125i that is aligned with an inner edge 20e of a respective pan 20₁, 20₂. However, the inner facing side 125i of a respective magnet 125m on the sidewalls 20w can extend inwardly, beyond the sidewalls 20w, a distance, such as a distance in a range of about 0.01-0.25 inches or be slightly recessed inward from the inner edge 20e of the sidewalls 20w, such as a distance in a range of about 0.01-0.25 inches.

The discrete magnets 25m can be planar, thin magnets having a thickness in a range of about 1/16 inch to about ¼ of an inch. All of the discrete magnets 25m and 125m can be the same (have the same configuration and material). The magnets 25m and 125m can be square with length and width dimensions of about 1 inch. Example magnets can have a rated holding power of about 42.5 lb or greater and a surface gauss rating of about 1700 or greater. Commercially available magnets are available from “Amazing Magnets: under product q063h. See, https://amazingmagnets.com/product/q063h/

FIG. 5B illustrates that the discrete magnets 25m′, 125m′ can be provided as elongate strips of magnets 25m′, 125m′ that can be arranged to provide the sets of magnets 251′, 1251′, 252′, 1252′.

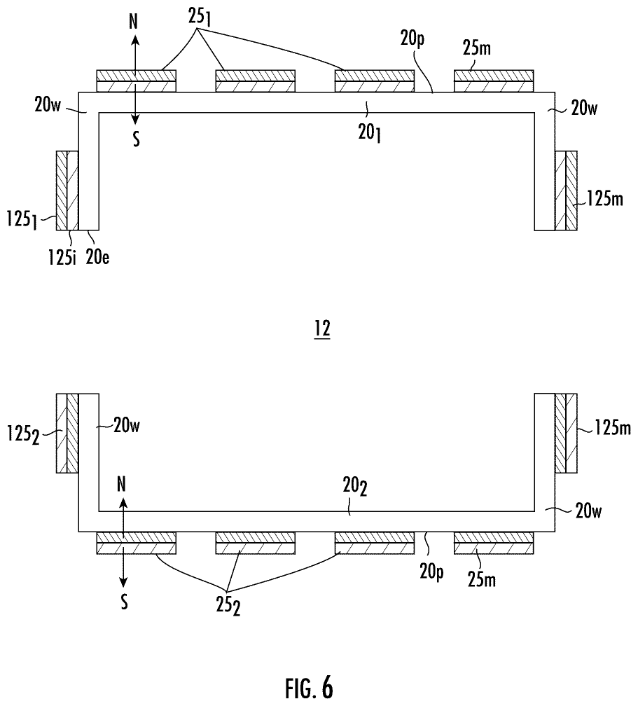

FIG. 6 illustrates example aligned (pole) orientations of magnets 25m, 125m relative to the respective pans 20₁, 20₂. The first pan 20₁ arranges the magnets 25m, 125m with a first pole direction (part of magnet with a first hatching, e.g., north or “N”) facing outward and an opposing pole direction facing inward (part of magnet with a second hatching, e.g., south or “S”). The second pan 20₂ arranges the magnets 25m, 125m with the opposing orientation, e.g., the first pole direction facing inward and the opposing pole direction facing outward. FIG. 6 also illustrates a different configuration of magnets 25m for the arrays 251, 252 on the respective pans 20₁, 20₂.

It is also noted that the magnets 25m, 25m′ and/or 125m, 125m′ may be arranged on an internal surface of the primary wall 20p rather than the external surface as shown. It is also noted that the magnets 125m on the sidewalls 20w can be provided in more than one aligned row, each row stacked one above another (not shown).

The transport container 10 can be configured to provide a magnetic field with a magnetic field strength of about 20 Gauss to about 80 Gauss over a volume of at least about 530 in³ of the internal chamber. The transport container 10 can be configured, in some embodiments, to allow a transport and/or storage time for the gas containers with hyperpolarized gas of about 1-3 hours without significant decay in polarization of the gas in the gas container(s) 200. “Significant decay” means that the polarized gas loses 50% or more of its original polarization value, with the “original polarization value” measured before the gas container 200, e.g., bag is placed into the transport container 10.

The magnetic field for the internal chamber 12 can be in a primarily unidirectional configuration with flux lines parallel and extending between, orthogonal to the primary walls 20w, not necessarily uniform in magnitude about the internal chamber 12.

The gas container 200 can hold a bolus or multiple bolus amount of hyperpolarized ¹²⁹Xe in a gaseous state for inhalation by a patient. The gas container 200 can be a bag 200b, such as a TEDLAR bag and can comprise a gas conduit 210. The gas container 200 can be held on-end with a long side facing down or up and the gas conduit 210 facing another bag 200. The internal chamber 12 can accommodate one or more bags, typically 2-3 bags 200b of the hyperpolarized ¹²⁹Xe in a gaseous state (shown as two side-by-side bags in FIG. 3). The bags 200 can each be oriented on-end in the internal chamber 12 with the outlet conduit/tube 210 facing a right or left side of the transport container, when the first and second pans are oriented horizontally.

The transport container 10 can be relatively light weight with a weight in a range of about 10 pounds to about 35 pounds, such as about 20 pounds. The transport container 10 can have a width and length in a range of 1-4 feet.

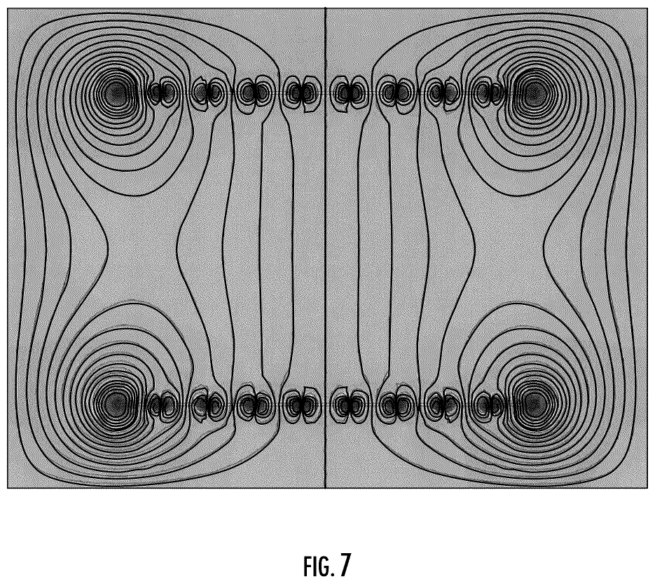

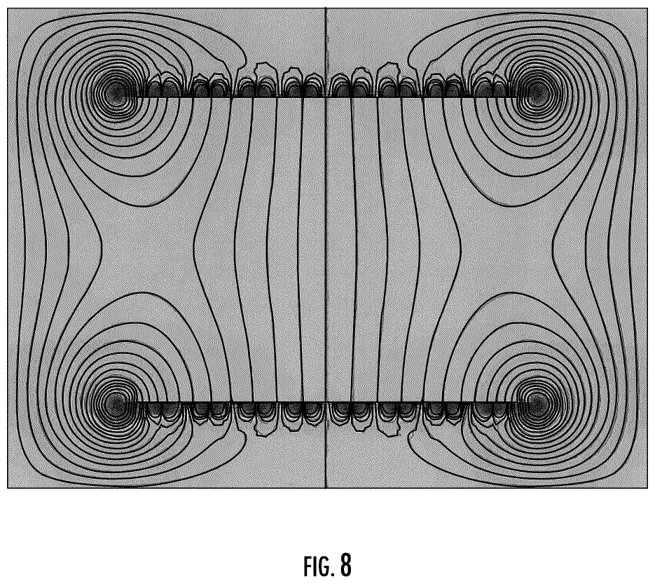

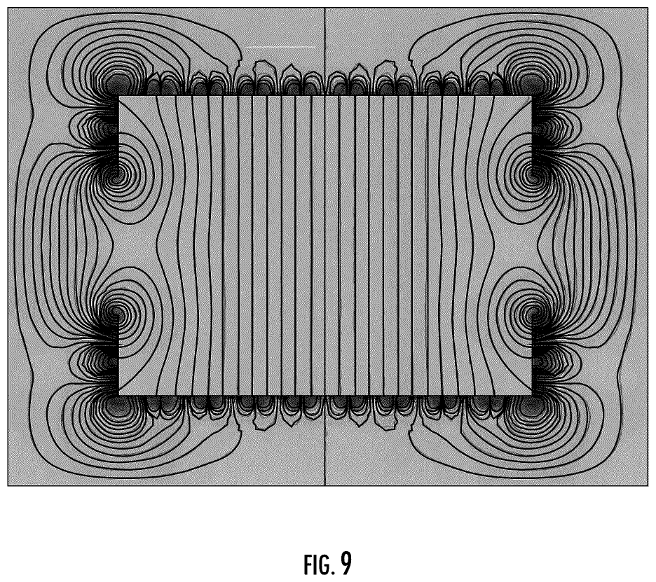

Turning now to FIGS. 7-9, simulated magnetic field direction and magnitude based on the use of discrete magnets alone and with pole pieces (pans) are shown. FIG. 7 shows a simulation of magnet arrays with discrete magnets alone, without pole pieces (without pans 20). FIG. 8 shows a simulation of magnet arrays with discrete magnets 25m and cooperating flat pole pieces (primary walls 20p of pans). FIG. 9 shows a simulation of magnet arrays with discrete magnets and cooperating flat pole pieces provided the primary wall 20p and sidewalls 20w with respective magnets 25m, 125m. The unidirectional flux lines are shown as parallel vertical lines inward of the right and left sides of the simulated magnetic field with the magnet/pole components included in the simulation shown in FIG. 9.

The foregoing is illustrative of the present invention and is not to be construed as limiting thereof. Although a few exemplary embodiments of this invention have been described, those skilled in the art will readily appreciate that many modifications are possible in the exemplary embodiments without materially departing from the novel teachings and advantages of this invention. Accordingly, all such modifications are intended to be included within the scope of this invention as defined in the claims. In the claims, means-plus-function clause are intended to cover the structures described herein as performing the recited function and not only structural equivalents but also equivalent structures. Therefore, it is to be understood that the foregoing is illustrative of the present invention and is not to be construed as limited to the specific embodiments disclosed, and that modifications to the disclosed embodiments, as well as other embodiments, are intended to be included within the scope of the appended claims. The invention is defined by the following claims, with equivalents of the claims to be included therein.

That which is claimed is:

1. A transport container for transporting one or more gas containers of hyperpolarized gas products, comprising:
a first pan having a first recessed chamber;
a second pan having a second recessed chamber, wherein the second pan is spaced apart from the first pan, aligned with and facing the first pan with the first recessed chamber facing the second recessed chamber;
a first set of magnets on the first pan; and
a second set of magnets on the second pan.

2. The transport container of claim 1, wherein the first and second pans are ferromagnetic metal.

3. The transport container of claim 1, further comprising at least one spacer positioned between the first pan and the second pan and defining at least part of an internal chamber.

4. The transport container of claim 1, further comprising a first spacer and a second spacer arranged between the first and second pans, wherein the first spacer has sidewalls that are shorter than sidewalls of the second spacer, and wherein the first and second spacers have an open center through channel that are aligned and cooperate with the first and second pans to provide at least part of an internal chamber configured to hold at least one gas container.

5. The transport container of claim 4, wherein the first and second spacers are rectangular and comprise a foam body.

6. The transport container of claim 4, wherein the second spacer has a lip that resides inside the second recessed chamber.

7. The transport container of claim 1, further comprising an outer case with cooperating first and second case members, wherein the outer case holds the first and second pans therein.

8. The transport container of claim 7, wherein the outer case has a polymer or co-polymer molded body.

9. The transport container of claim 1, wherein the first and second pans each comprise a respective primary wall and four sidewalls, wherein the four sidewalls define a perimeter of a respective pan, are orthogonal to the primary wall and surround the respective recessed chamber under or above the primary wall, and wherein the first and second sets of magnets comprise rare earth permanent magnets.

10. The transport container of claim 9, wherein the rare earth permanent magnets comprise neodymium.

11. The transport container of claim 9, wherein the first and second sets of magnets are arranged in rows and columns or rows or columns across and/or along the primary wall of respective first and second pans and also include at least one row arranged to extend across each of the four sidewalls.

12. The transport container of claim 1, wherein the first and second sets of magnets comprise neodymium and are arranged in the columns and rows on the primary wall of respective first and second pans.

13. The transport container of claim 12, further comprising a single row of permanent magnets comprising neodymium arranged about each of four sidewalls of each of the first and second pans, wherein the single row is spaced inwardly apart a distance from the primary wall to define a gap space therebetween.

14. The transport container of claim 1, wherein the first and second sets of magnets are provided as closely spaced planar magnets, and wherein the planar magnets are rare earth magnets.

15. The transport container of claim 1, wherein the first and second pans are galvanic steel.

16. The transport container of claim 1, wherein the first and second sets of magnets define a magnetic field in a range of about 20 Gauss to about 80 Gauss over a volume of about 530 in³ of the internal chamber.

17. The transport container of claim 1, wherein the transport container has a weight in a range of about 10 pounds to about 25 pounds.

18. The transport container of claim 1, wherein the magnets of the first and second sets of magnets have a common size and shape with a thickness in a range of about 1/16 inch to about ¼ of an inch, and wherein the magnets have a rated holding power of about 42.5 lb or greater and a surface gauss rating of at least about 1700.

19. The transport container of claim 1, further comprising at least one bag of hyperpolarized ¹²⁹Xe gas in the internal chamber.

20. The transport container of claim 19, wherein the at least one bag of hyperpolarized ¹²⁹Xe gas in the internal chamber is three, each oriented on-end with an outlet tube facing a right or left side of the transport container, when the first and second pans are oriented horizontally.

21. The transport container of claim 1, wherein the first and second pans are polygonal and have a length and a width in a range of 9 inches to 2 feet.

22. The transport container of claim 8, wherein the primary walls have a length and width in a range of about 9 inches to about 2 feet, and wherein the sidewalls have a height in a range of one inch to five inches, optionally about two inches.

23. The transport container of claim 1, further comprising an outer case with a lid and a bottom, wherein the lid holds the first pan and a first foam spacer and pivots away from the bottom to open and close, and wherein the bottom holds the second pan and a second foam spacer facing the first foam spacer.

24. The transport container of claim 23, wherein the first foam spacer has a first open channel and the second foam spacer has a second open channel, wherein the first open channel is aligned with the second open channel and the first and second open channels define at least a portion of the internal chamber.

25. The transport container of claim 24, wherein the first foam spacer and/or the second foam spacer are configured to hold the at least one gas container between the first and second pans.
